(19) United States
(12) Patent Application Publication
(10) Pub. No.: US 2013/0222726 A1
(43) Pub. Date: Aug. 29, 2013

(54) LIQUID CRYSTAL DISPLAY DEVICE AND METHOD OF FABRICATING THE SAME

(71) Applicant: LG Display CO., LTD., (US)

(72) Inventors: SeungKyu Choi, Paju (KR); JoonYoung Yang, Wonmi-Gu (KR)

(73) Assignee: LG DISPLAY CO., LTD., Seoul (KR)

(21) Appl. No.: 13/725,329

(22) Filed: Dec. 21, 2012

(30) Foreign Application Priority Data
Feb. 24, 2012 (KR) 10-2012-0019320

(51) Int. Cl. G02F 1/1362; H01L 33/08

(52) U.S. Cl. CPC G02F 1/136286; H01L 33/08
USPC 349/43; 438/30

(57) ABSTRACT

A method of fabricating a liquid crystal display device includes a gate line and a gate electrode on the first substrate; a first insulating layer over the first substrate; an active; a source electrode and a drain electrode on the active layer, the source electrode and the drain electrode including a first conductive layer, a transparent conductive layer and a second conductive layer being sequentially formed; a data line formed by the transparent conductive layer and the second conductive layer; a pixel electrode formed by the transparent conductive layer; an organic insulating layer on the data line; a second insulating layer over the entire upper surface of the first substrate; a common electrode overlap with the pixel electrode and the organic insulating layer, and the common electrode and the pixel electrode generating a fringe electric field.

### CROSS-REFERENCE TO RELATED APPLICATION

Pursuant to 35 U.S.C. §119(a), this application claims the benefit of earlier filing date and right of priority to Korean Application No. 10-2012-0019320, filed on Feb. 24, 2012, the contents of which is incorporated by reference herein in its entirety.

### BACKGROUND

1. Field of the Disclosure

The present disclosure relates to a liquid crystal display device and a method of fabricating the same, and particularly, to a liquid crystal display device for achieving improved transmittance and aperture ratio and reduced parasitic capacitance, and a method of fabricating the same.

2. Background

A flat panel display such as a liquid crystal display device is provided with an active device such as a thin film transistor in each pixel to drive the display device. This type of driving of the display device is generally called active matrix driving. In the active matrix driving, the thin film transistor is located in each pixel to drive the corresponding pixel.

The configuration of the liquid crystal display device will now be described in detail with reference to FIGS. 1 and 2.

FIG. 1 illustrates a top view of a unit pixel in a conventional liquid crystal display device, and FIG. 2 illustrates a cross-sectional view taken along areas A1-A2 and B1-B2 of FIG. 1.

The liquid crystal display device is a fringe field switching liquid crystal display device in which a common electrode 50 and a pixel electrode 70 form a fringe electric field with an insulating layer interposed therebetween. This liquid crystal display device includes a liquid crystal panel displaying an image, a backlight unit (not shown) emitting light, and a driving circuit (not shown) driving the liquid crystal panel and the backlight unit (not shown). Here, the liquid crystal panel includes a thin film transistor substrate 10, a color filter substrate (not shown), and a liquid crystal layer (not shown), and FIG. 1 illustrates the thin film transistor substrate 10.

The thin film transistor substrate 1 includes a gate line 11, a data line 50, a thin film transistor (TFT) T, a pixel electrode 70, a common electrode 90, a gate pad GP, and a data pad DP.

The gate line 11 and the data line 50 are provided in plurality and arranged to intersect each other, and the intersection of the gate and data lines 11 and 50 define a plurality of pixel areas.

The gate line 11 and the data line 50 receive a gate driving signal and a data driving signal from an external circuit via the gate pad GP and the data pad DP, respectively.

The gate driving signal and the data driving signal are applied to the thin film transistor T located in each pixel area. Here, the thin film transistor T may include a gate electrode 10, a first insulating layer 20, an active layer 30, an ohmic contact layer 40, a source electrode 51, and a drain electrode 52.

The pixel electrode 70 connected to the drain electrode 52 of the thin film transistor T receives a data driving signal according to the channel's on/off state based on a gate driving signal. The pixel electrode 70 also forms a fringe electric field together with the common electrode 90 receiving a common voltage according to the data driving signal, and thus drives the liquid crystal layer (not shown).

Since the pixel electrode 70 is formed in a transparent area, the pixel electrode 70 is formed of a transparent conductive material, such as indium tin oxide (ITO) or indium zinc oxide (IZO). Therefore, the pixel electrode 70 and the drain electrode 52, which is formed of a opaque conductive material, are provided in different layers and electrically contact each other via a contact hole 65 in order to receive a data driving signal.

Here, the contact hole 65 overlaps the drain electrode 52 and thus does not allow light transmission, and is therefore covered by a black matrix formed on a second substrate (not shown). That is, the contact hole 65 so formed causes a decrease in aperture ratio.

Furthermore, the process for fabricating the liquid crystal display device includes forming the source and drain electrodes 51 and 52, and the data line 50, followed by forming a second insulating layer 60 and the pixel electrode 70. Therefore, the data line 50 and the pixel electrode 70 are formed by different mask processes.

However, the mask processes cannot be carried out with 100% precision. That is, a mask for forming pixel electrodes 70, when aligned on the first substrate, cannot always be located at the same location, which results in slight variations in the location of the pixel electrodes 70 within an allowable tolerance range in each process.

Since different mask processes are used for the data line 50 and the pixel electrodes 70, the distances d1 and d2 from the data line 50 to the pixel electrodes 70 formed at both sides of the data line 50 are not always the same as shown in area B1-B2 of FIG. 2. At this time, the data line 50, the second insulating layer 60 and the pixel electrodes 70 serve as one parasitic capacitor, and the different distances d1 and d2 may cause different parasitic capacitance at both sides of the data line 50.

This parasitic capacitance acts as load to a data driving signal delivered by the data line 50, and the difference in the parasitic capacitance may cause the inconsistent delivery of the data driving signal, thereby resulting in the faulty driving of the liquid crystal display device.

### SUMMARY

A liquid crystal display device includes: a first substrate; a gate line and a gate electrode on the first substrate; a first insulating layer over the first substrate having the gate line and the gate electrode; an active layer on the first insulating layer; a source electrode and a drain electrode on the active layer, the source electrode and the drain electrode including a first conductive layer, a transparent conductive layer and a second conductive layer being sequentially formed; a data line connected to the source electrode on the first insulating layer, the data line being formed by the transparent conductive layer and the second conductive layer; a pixel electrode connected to the drain electrode on the first insulating layer, the pixel electrode being formed by the transparent conductive layer; an organic insulating layer on the data line; a second insulating layer over the entire upper surface of the first substrate having the organic insulating layer; a common electrode on the second insulating layer to be overlap with the pixel electrode and the organic insulating layer, and the common electrode and the pixel electrode generating a fringe electric field; a second substrate attached to the first substrate; and a liquid crystal layer between the first substrate and the second substrate.

A method of fabricating a liquid crystal display device includes: forming a gate line and a gate electrode on a first substrate; sequentially forming a first insulating layer, an active layer and a first conductive layer over the first substrate; sequentially forming a transparent conductive layer and a second conductive layer on the first insulating layer having the active layer and the first conductive layer thereon; patterning the first conductive layer, the transparent conductive layer, and the second conductive layer by single mask process to form source and drain electrodes having the first conductive layer, the transparent conductive layer and the second conductive layer, a data line having the transparent conductive layer and the second conductive layer, and a pixel electrode having the transparent conductive layer; introducing a liquid crystal layer between the first substrate and the second substrate; and attaching a second substrate to the first substrate, wherein the distance between the pixel electrode and the data line is same as the distance between the neighboring pixel electrode and the data line.

### BRIEF DESCRIPTION OF THE DRAWINGS

The accompanying drawings, which are included to provide a further understanding of the invention and are incorporated in and constitute a part of this specification, illustrate exemplary embodiments and together with the description serve to explain the principles of the invention.

In the drawings:

FIG. 1 illustrates a top view of a unit pixel in a conventional liquid crystal display device;

FIG. 2 illustrates a cross-sectional view taken along areas A1-A2 and B1-B2 in FIG. 1;

FIG. 3A illustrates a top view of a unit pixel in a liquid crystal display device according to a first embodiment of the present invention;

FIG. 3B illustrates a cross-sectional view taken along areas I-I′, II-II′, III-III′ and IV-IV′ in FIG. 3A;

FIG. 4 illustrates a cross-sectional view of a liquid crystal display device according to a second embodiment of the present invention; and

FIGS. 5A through 5M illustrate cross-sectional views depicting a method of fabricating a liquid crystal display device according to a second embodiment of the present invention.

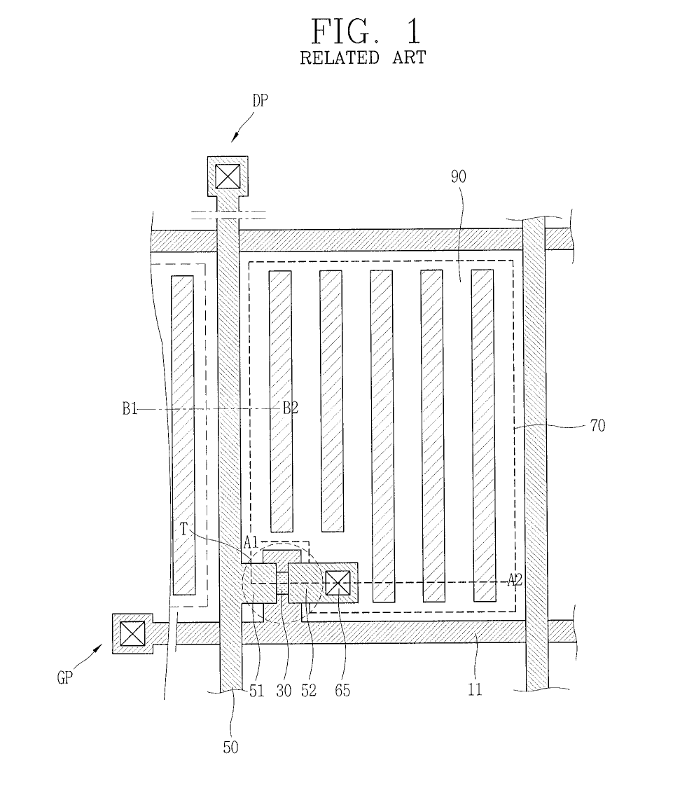

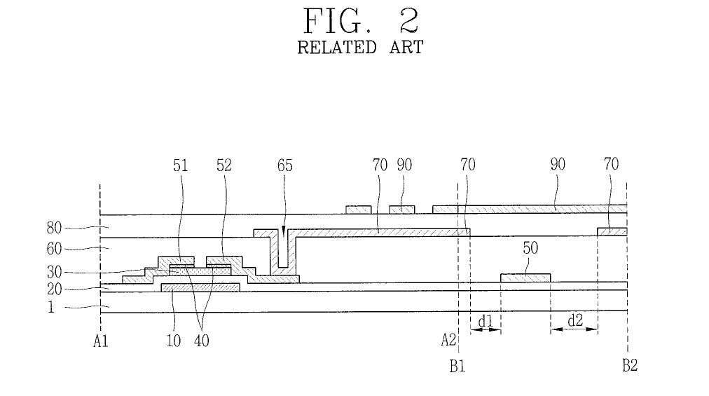

### DETAILED DESCRIPTION OF THE EXEMPLARY EMBODIMENTS

Description will now be given in detail of the exemplary embodiments, with reference to the accompanying drawings. For the sake of brief description with reference to the drawings, the same or equivalent components will be provided with the same reference numbers, and description thereof will not be repeated.

Hereinafter, a liquid crystal display device and a method of fabricating the same according to exemplary embodiments of the present invention will be described in more detail with reference to accompanying drawings.

In this specification, identical or like reference numerals are used for identical or like reference configuration even between different embodiments, in which case the initial description thereof is applied throughout.

Terms expressed in singular in this specification may encompass the plural sense unless explicitly stated otherwise in the context.

Furthermore, it should be noted that components denoted in the accompanying drawings of this specification may not be necessarily drawn to scale for ease of description.

The terms “first”, “second”, “third” and the like in this specification are used to describe various elements; however, these terms are intended only for distinguishing between elements and is not intended to be limiting.

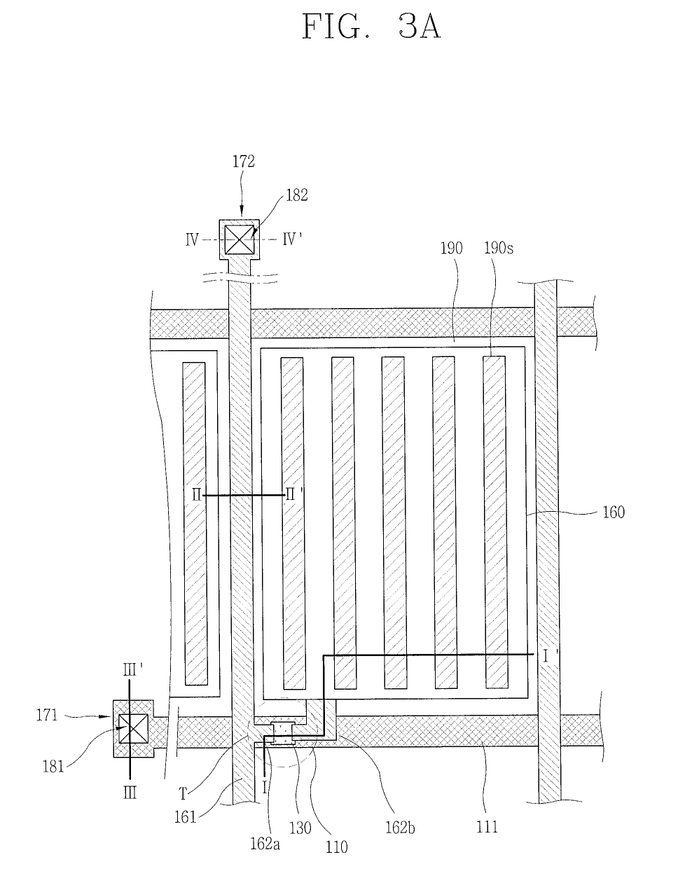

FIG. 3A illustrates a top view of a unit pixel in a liquid crystal display device according to a first embodiment of the present invention, and FIG. 3B illustrates a cross-sectional view taken along areas I-I′, II-II′, and IV-IV′.

The liquid crystal display device according to the first embodiment of the present invention includes a liquid crystal panel (not shown), a backlight unit (not shown), and a driving circuit (not shown). Here, the liquid crystal panel includes a first substrate 100, a second substrate (not shown), and a liquid crystal layer (not shown), the backlight unit (not shown) includes a light source for emitting light to the liquid crystal panel, and the driving circuit (not shown) may include a plurality of driving chips and connection wires for driving the backlight unit (not shown) and the liquid crystal panel (not shown). Hereinafter, the construction on the first substrate 100 will be described in detail.

First, referring to FIG. 3A, the first substrate 100 may include a gate line 111, a data line 161, a gate pad, a data pad, a thin film transistor (T), a common electrode 190, and a pixel electrode 160.

The data line 161 and the gate line 111 may intersect each other on the first substrate 100. Although linearly illustrated in the drawing, the data line 161 may be formed in an S shape curved at a predetermined angle. Here, the space defined by the intersection of the data line 161 and the gate line 111 is called a unit pixel (not shown), and such unit pixels (not shown) may be arranged in matrix configuration on the entire surface of the first substrate 100.

The gate pad is formed at one end of the gate line 111, and a data pad is formed at one end of the data line 161.

The gate pad, referring to FIG. 3B, includes a first contact hole 181 and a gate connection pattern, and the gate connection pattern electrically contacts one end of the gate line 111 via the first contact hole 181. The gate pad 171 serves to apply a gate driving signal from a driving circuit to the gate line 111. The data pad, referring to FIG. 3B, includes a second contact hole 182 and a data connection pattern, and the data connection pattern electrically contacts one end of the data line 161 via the second contact hole 182. The data pad serves to apply a data driving signal from the driving circuit to the data line 161.

The thin film transistor T is a switching device and may includes a gate electrode 110, a first insulating layer 120, an active layer 130, an ohmic contact layer 140, and source and drain electrodes 162a and 162b.

The gate electrode 110 corresponds to part of the gate line 111 and is configured to receive a gate driving signal. Other configuration of the thin film transistor T overlaps the gate electrode 110, so the other configuration may also overlap the gate line 111. That is, the thin film transistor T may overlay the gate line 111. However, if the gate electrode 110 extends in one direction from the gate line 111, the thin film transistor T may be formed in one area of the unit pixel (not shown), not on the gate line 111.

The first insulating layer 120 is formed on the entire surface of the first substrate 100 including the upper part of the gate electrode 110 in order to insulate the gate electrode 110 from the active layer 130.

The active layer 130 is formed on the first insulating layer in the region overlapping the gate electrode 110. The active layer 130 is the area where a channel is formed, and may be formed of a semiconductor including amorphous silicon and polycrystalline silicon.

The ohmic contact layer 140 is formed between the active layer 130 and the source and drain electrodes 162a and 162b to be described later. The ohmic contact layer 140 is provided to facilitate electric contact between the active layer 130 and the source and drain electrodes 162a and 162b. The ohmic contact layer 140 may be formed of heavily-doped n-type or p-type silicon.

In the case that the active layer 130 is formed of an oxide semiconductor, an etch stopper, instead of the ohmic contact layer 140, may be formed on the oxide semiconductor so as to prevent the channel area from being damaged by etching. The oxide semiconductor has an electron drift velocity at least ten times greater than that of amorphous silicon and is thus advantageous in implementing high resolution and high-speed driving.

The source and drain electrodes 162a and 162b are formed on the ohmic contact layer 140 in one region over the first insulating layer 120. Here, the data line 161 is in connection with the source electrode 162a and is formed simultaneously with the source and drain electrodes 162a and 162b. Thus, the source electrode 162a serves to deliver a gate driving signal applied from the data line 161, and the drain electrode 162b serves to receive the data driving signal via the channel of the active layer 130.

Here, referring to FIG. 3B, the source and drain electrodes 162a and 162b may be constituted by a first conductive layer 151, a transparent conductive layer 152, and a second conductive layer 153, and the data line 161 may be constituted by the transparent conductive layer 152 and the second conductive layer 153.

The first conductive layer 151 is in contact with the ohmic contact layer 140 and the transparent conductive layer 152 so it may be formed of a material having good ohmic-contact properties in order to facilitate signal delivery to the transparent conductive layer 152. For example, the first conductive layer 151 may be formed of any one of Mo, MoTi, Ti, or Ti alloy. The transparent conductive layer 152 is also used as a material of the pixel electrode 160 to be described later so it may be formed of indium tin oxide (ITO) or indium zinc oxide (IZO) having transparent properties. Also, the second conductive layer 153 may be formed of any one of Cu, Al, Ag, Pt, or Au in order to form low-resistance wiring.

The first conductive layer 151 is patterned in the same shape as the ohmic contact layer. The transparent conductive layer 152 and the second conductive layer 153 are also patterned in the same shape except for the region in which the pixel electrode 160 is formed. Here, the ohmic contact layer, the first conductive layer 151, the transparent conductive layer 152, and the second conductive layer 153 on the active layer 130 are patterned in the same shape because the pattern above the active layer 130 is formed through one mask process.

The pixel electrode 160 is constituted by the transparent conductive layer 152, and may be connected to the transparent conductive layer 152 of the drain electrode 162. In this case, the pixel electrode 160 is characterized as being directly connected to the drain electrode 162b in the same layer without a contact hole.

Accordingly, the absence of the contact hole and the formation of the thin film transistor T on the gate line 111 can lead to an increase in transparent area within the unit pixel. In this case, a black matrix is formed only in the region corresponding to the data line 161 and the gate line 111. Therefore, the liquid crystal display device according to the first embodiment of the present invention can have the improved aperture ratio of the liquid crystal display device.

Also, the transparent conductive layer 152 and the second conductive layer 153 are patterned simultaneously, and the data line 161 and the pixel electrode 160 are formed at the same time through a single mask process. Therefore, a difference in distances from the data line 161 to adjacent pixel electrodes 160 can be eliminated, which has conventionally occurred due to the use of different mask processes. That is, distances d1 and d2 in FIG. 3B can be rendered identical to each other.

Accordingly, a difference in parasitic capacitance formed between the pixel electrode and each side of the data line is eliminated at both sides of the data line.

Meanwhile, a second insulating layer 180 may be formed on the first substrate 100 having the pixel electrode 160 and the thin film transistor T thereon. The second insulating layer 180 may be formed of an organic material such as photo acryl, poly vinyl alcohol (PVA) or benzocyclobutene (BCB), or an inorganic material such as SiNx or SiO2.

A common electrode 190 may be formed on the second insulating layer 180. The common electrode 190 may be formed on the entire top surface of the second insulating layer 180 and may include a plurality of slits 190 in its region overlapping the pixel electrode 160 in order to form a fringe electric field. The common electrode 190 may be formed of indium tin oxide (ITO) or indium zinc oxide (IZO) which are the same as those used for the pixel electrode 160.

However, even if a different distance between the data line 161 and each pixel electrode 160 is eliminated, this can only eliminate variations of parasitic capacitance and cannot reduce the parasitic capacitance itself. Therefore, to solve this limitation, the configuration of a liquid crystal display device according to a second embodiment of the present invention will now be described with reference to FIG. 4.

FIG. 4 illustrates a cross-sectional view of a liquid crystal display device according to the second embodiment of the present invention.

The liquid crystal display device according to the second embodiment of the present invention further includes an organic insulating layer 270 in addition to the previous embodiment components.

The organic insulating layer 270 may be formed on a data line 261 and can serve to reduce the parasitic capacitance which may occur between the data line 261 and a common electrode 290.

The common electrode 290 may be formed on the entire surface of the first substrate excluding the region above a thin film transistor and a plurality of slit regions in the upper portion of the pixel electrode 260. Therefore, the common electrode 290 may overlap the data line 261 with a second insulating layer interposed therebetween. In this case, the common electrode 290, the data line 261 and the second insulating layer 280 may act as one parasitic capacitor. It is preferred that such a parasitic capacitor have capacitance as low as possible since it may delay a data driving signal to thus cause signal distortion.

Therefore, the organic insulating layer 720 is formed of an organic material such as photo acryl, poly vinyl alcohol (PVA) or benzocyclobutene (BCB) to thereby lower the dielectric constant of the parasitic capacitance, and also lowers the parasitic capacitance by increasing the distance between the data line 261 and the common electrode 290.

Here, since the organic insulating layer 270 is used to lower the parasitic capacitance between the data line 261 and the common electrode 290, forming the organic insulating layer 270 in one region covering the top and both side portions of the data line 261 is enough. In particular, the organic insulating layer 270 is disposed over the data line 261 and in the space from the data line 261 to the adjacent pixel electrodes 260.

Preferably, the organic insulating layer 270 may have a thickness in the range of 1.5 μm to 2.5 μm.

Furthermore, the organic insulating layer 270 may be formed by coating, which require shorter process time than in the case of an inorganic material (SiNx or SiO2) processed by deposition.

Also, the sectional shape of the organic insulating layer 270 is not limited, and may have one of various polygonal shapes as well as a curved shape depicted in FIG. 4.

Meanwhile, the second insulating layer 280 formed on the organic insulating layer 270 in the second embodiment may be formed of an organic material such as SiNx or SIO2.

Also, in the second embodiment of the present invention, negative-type liquid crystal may be disposed over the region in which the organic insulating layer 270 is formed.

The organic insulating layer 270 creates a height difference between the organic insulating layer 270 area and the pixel area including the common electrode 290 and the pixel electrode 260. This height difference may result in the defective alignment of liquid crystal in the region where the height difference has occurred. In this case, sine the pre-tilt of liquid crystal molecules varies between regions, the alignment of liquid crystal also varies. Such a change in the alignment of liquid crystal may be the cause of varying light transmittance (i.e., the cause of disclination), which results in deteriorated image quality such as negative shading and afterimages or the like.

The disclination can be prevented by providing negative-type liquid crystal in the liquid crystal layer over the organic insulating layer 270, wherein the negative-type liquid crystal is aligned vertically relatively to the parabolic electric field formed over the organic insulating layer 270.

The second embodiment of the present invention has the same configuration as that of the first embodiment, except for the organic insulating layer 270 and the negative-type liquid crystal, and the description of the first embodiment is therefore applied to the rest of the configuration of the second embodiment. Here, reference numerals of FIGS. 3A and 3B corresponding to those of FIG. 4 indicate the same configuration. For example, reference numerals 220 and 230 in FIG. 3, and reference numerals 220 and 230 in FIG. 4 designate the same configuration.

A method of fabricating the liquid crystal display device according to the first and second embodiments of the present invention will now be described in detail.

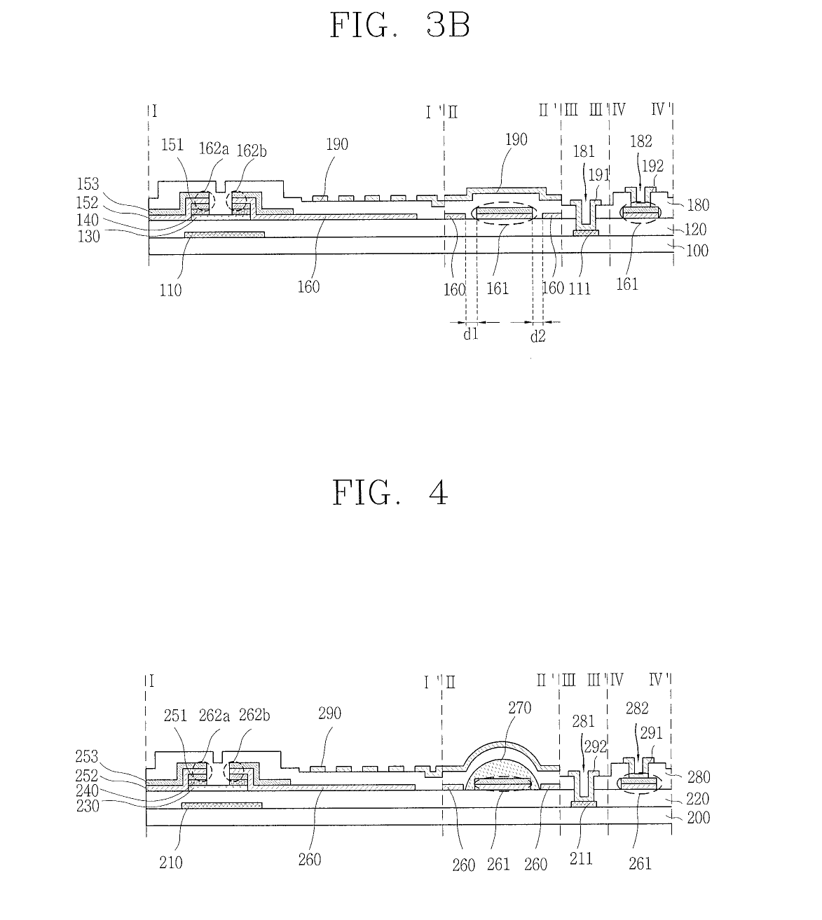

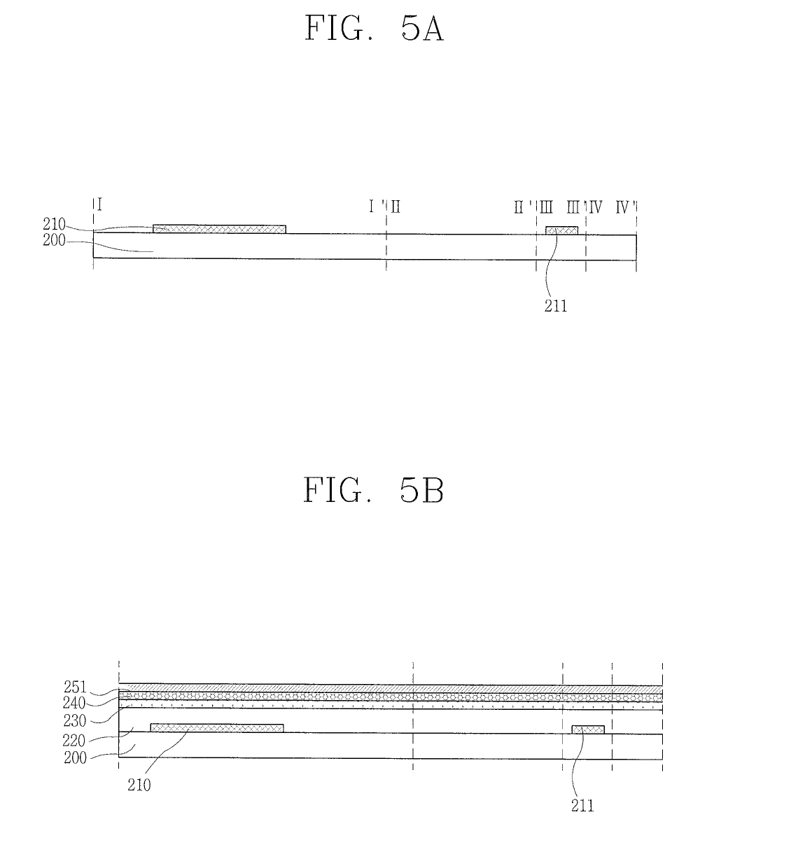

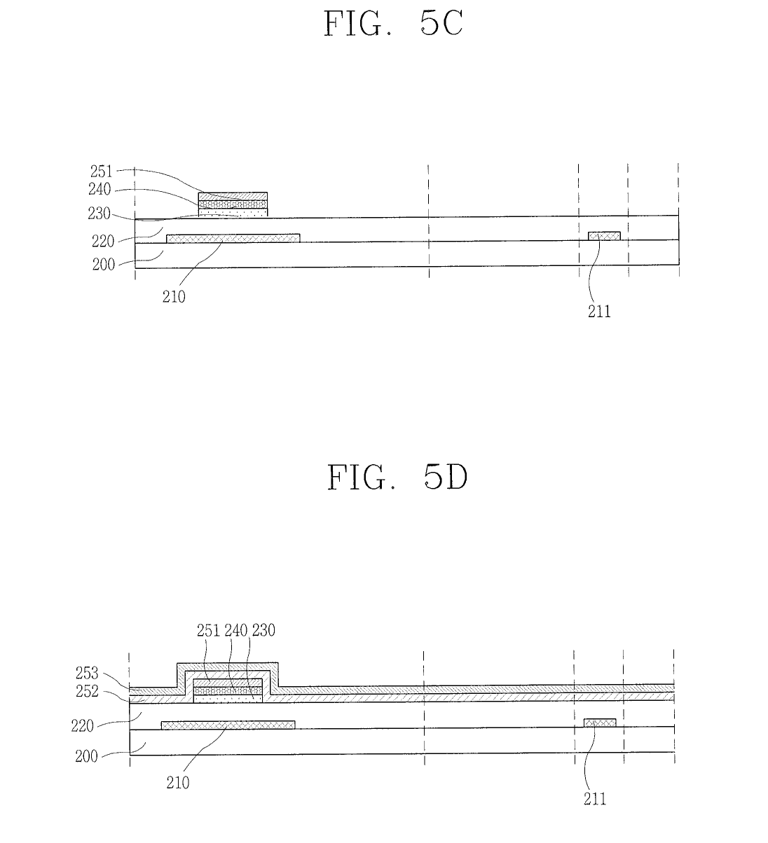

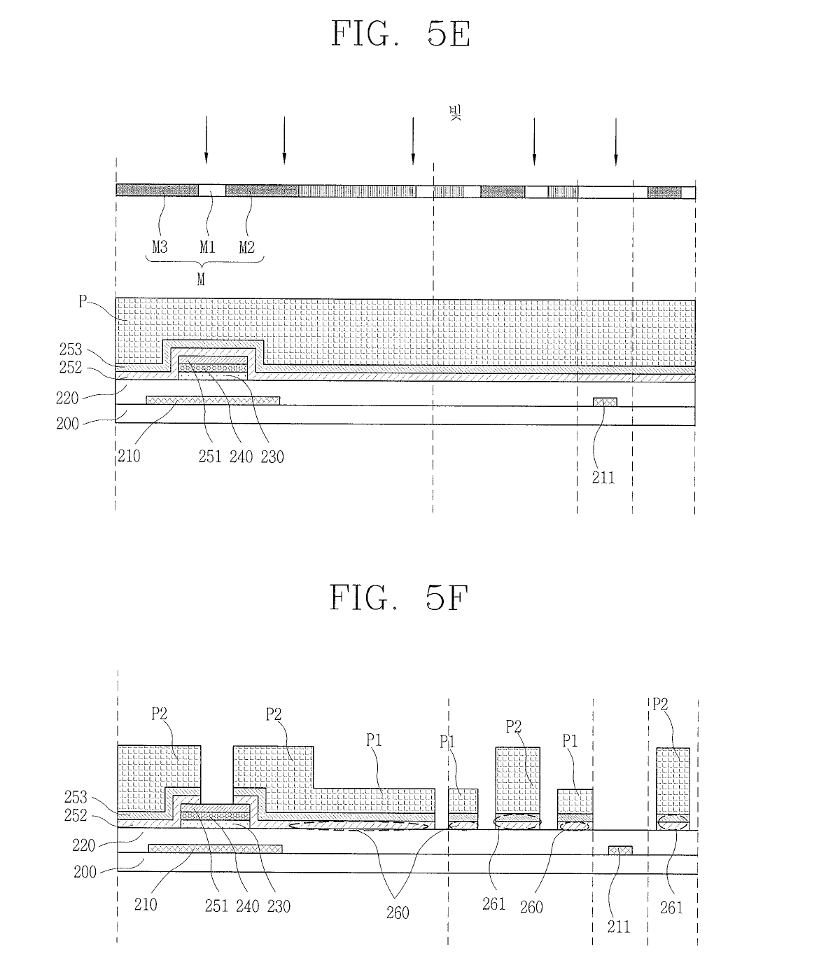

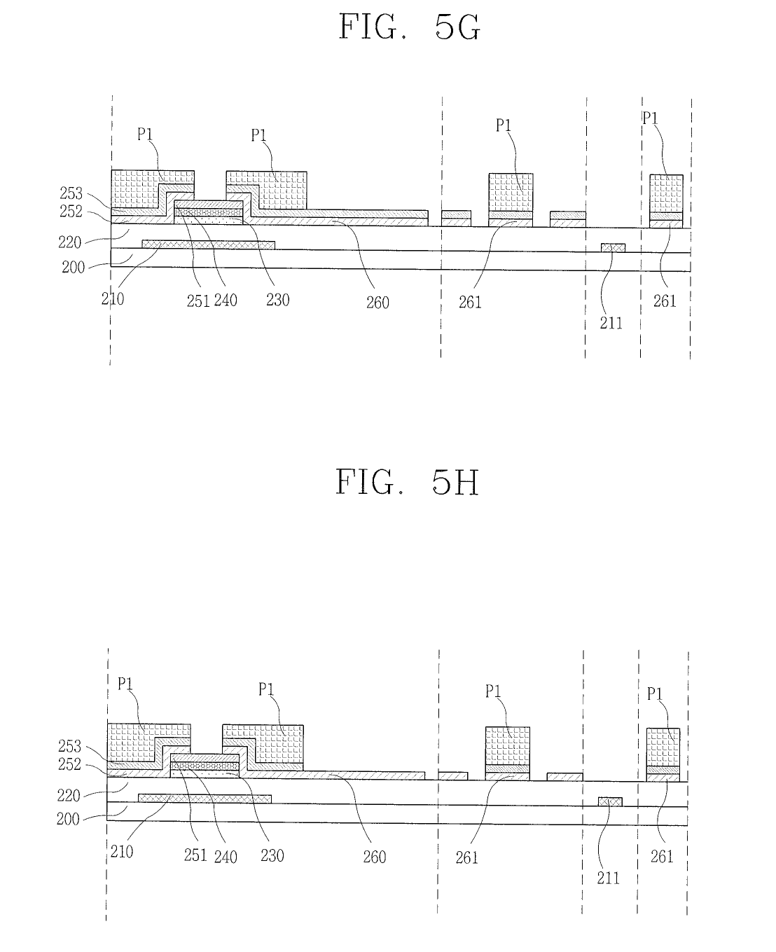

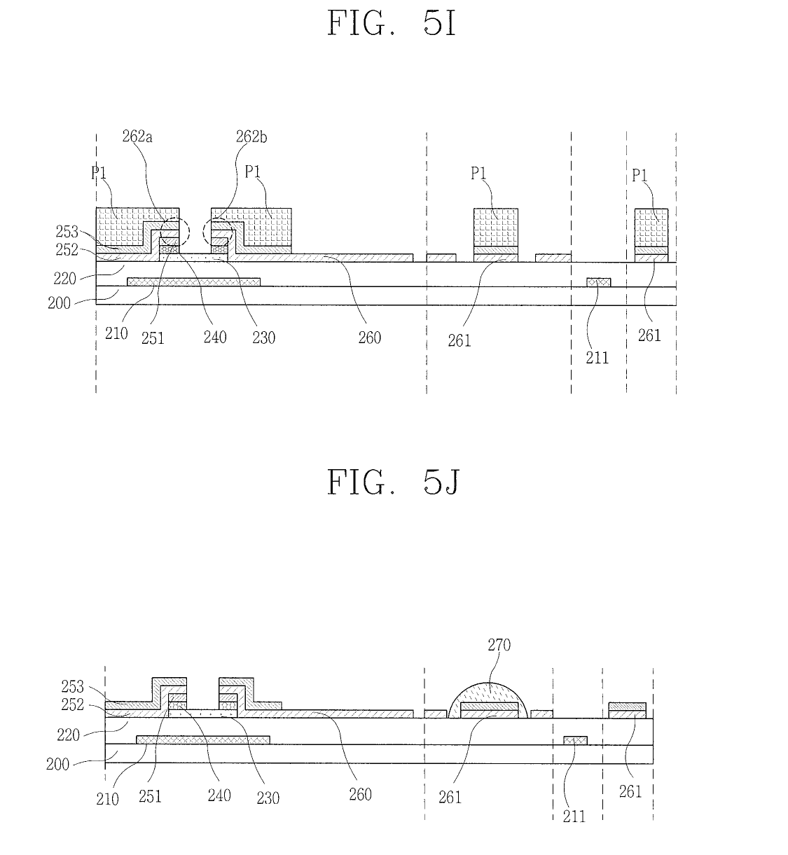

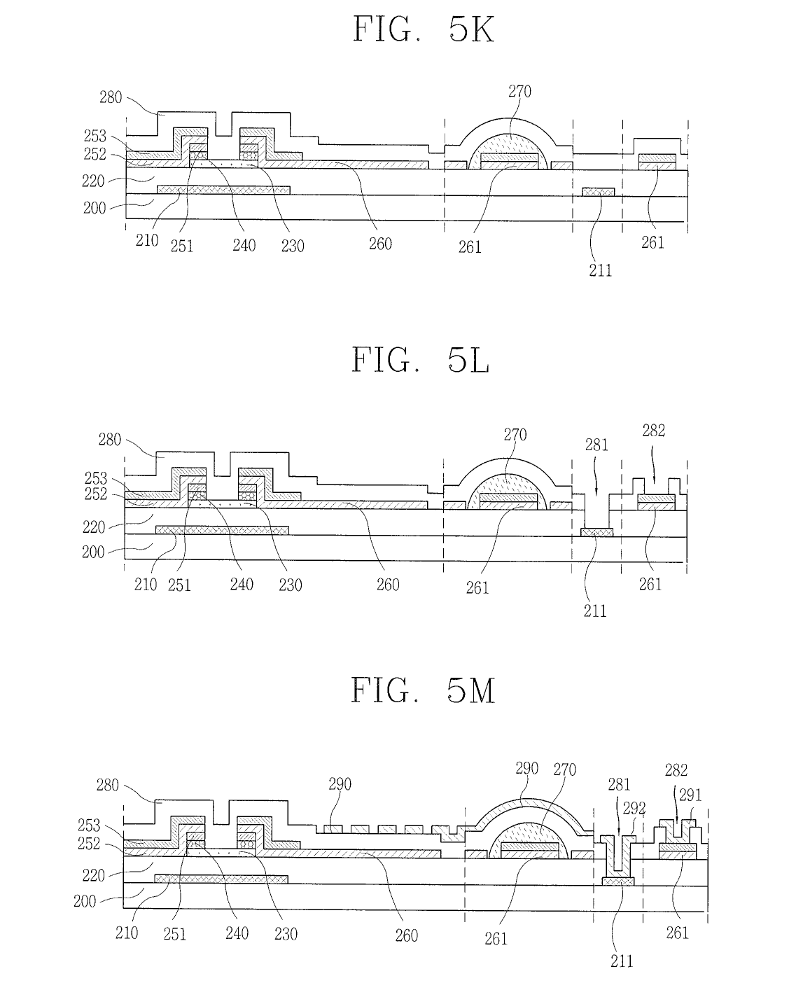

FIG. 5A through 5M are cross-sectional views for showing a method of the liquid crystal display device according to the second embodiment of the present invention. Areas I-I′, II-II′, and IV-IV′ in the drawings denote a thin film transistor region, a data line 261 region, a gate pad region, and a data pad region, respectively.

The method of fabricating the liquid crystal display device according to the first embodiment of the present invention is identical to the method of fabricating the liquid crystal display device according to the second embodiment, except for forming an organic insulating layer 270. Therefore, the method of fabricating the liquid crystal display device according to the second embodiment encompasses the method of fabricating the liquid crystal display device according to the first embodiment of the present invention. So the description of the method of fabricating the liquid crystal display device according to the first embodiment is replaced with the description of the method of fabricating the liquid crystal display device according to the second embodiment.

First, referring to FIG. 5A, a gate electrode 210 and a gate line 211 are formed on a first substrate 200 through a first mask process. The first mask process refers to a photolithography process performed using a single mask.

Here, the gate electrode 210 is included in the gate line 211 as part of the gate line 211, and the gate line 211 may extend to the gate pad region. Also, the gate electrode 210 and the gate line 211 may be formed of a low-resistance opaque conductive material, such as aluminum (Al), aluminum alloy (Al alloy), tungsten (W), copper (Cu), nickel (Ni), chrome (Cr), molybdenum (Mo), titanium (Ti), platinum (Pt), or the like. Meanwhile, the gate electrode 210 may extend from the gate line 211 in one direction.

Subsequently, as shown in FIG. 5B, a second mask process begins with sequentially stacking a first insulating layer 220, an active layer 230, an ohmic contact layer 240, and a first conductive layer 251 on the gate electrode 210 and the gate line 211.

The first insulating layer 220 may be formed of an organic material or an inorganic material such as SiO2 or SiNx. The active layer 230 may be formed of a silicon semiconductor such as amorphous silicon or polycrystalline silicon, the ohmic contact layer 240 may be formed of an n-type or p-type doped silicon semiconductor, and the first conductive layer 251 may be formed of any one of Mo, MoTi, Ti, Ti alloy, or Al which facilitates electrical contact with the ohmic contact layer 240 and the active layer 230.

Meanwhile, if the active layer 230 is formed of an oxide semiconductor, an etch stopper layer of an inorganic material may be formed instead of the ohmic contact layer 240.

Subsequently, as shown in FIG. 5C, the active layer 230, the ohmic contact layer 240 and the first conductive layer 251 may be patterned simultaneously by a second mask. That is, a photoresist layer may be applied onto the first substrate 1200 and subjected to light exposure, developing, and etching, thereby forming the active layer 230, the ohmic contact layer 240 and the first conductive layer 250 to have the same shape.

Here, the second mask process is a process ultimately for patterning the active layer 230, so the patterned active layer 230, ohmic contact layer 240 and first conductive layer 251 may be positioned to overlap the gate electrode 251.

Thereafter, as shown in FIG. 5B, a third mask process beings with sequentially stacking a transparent conductive layer 252, and a second conductive layer 253 on the entire upper surface of the first substrate 200.

The transparent conductive layer 252 constitutes a pixel electrode 260, and may be formed of a transparent material such as indium tin oxide (ITO) or indium zinc oxide (IZO). The second conductive layer 253 constitutes source and drain electrodes 262a and 262b and a data line 261, and may be formed of any one of Cu, Al, Ag, Pt or Au, which is a low-resistance conductive material.

Subsequently, as shown in FIG. 5E, a photoresist layer P is applied onto the entire top surface of the first substrate 200, and may be subjected to exposure through a third mask.

In the application of the photoresist layer P, either positive or negative photoresist may be used, but the positive photoresist is preferred.

At the time of exposure, a half-tone mask or a slit mask may be used as the third mask M. The difference between the half-tone mask and the slit mask is that the former uses a translucent material while the latter uses diffraction of light through slits. However, both the half-tone mask and the slit mask define a shielding region, a translucent region and transparent region to thereby form a photoresist layer P with varying thickness.

Here, the third mask M has a transparent portion M1, a translucent portion M2 and a shielding portion M3. The third mask M is defined such that the transparent portion M1 corresponds to a channel region of the active layer 230, a boundary between the data line 251 and the pixel electrode 260 and the like, the translucent portion M2 corresponds to the region where the pixel electrode 260 is formed, and the shielding portion M3 corresponds to the region where the source and drain electrodes 262a and 262b and the data line 261 are formed.

Subsequently, as shown in FIG. 5F, a developing operation and a first etching operation is carried out to thereby form the pixel electrode 200 and the data line 261.

As a result of the developing operation, the photoresist layer P corresponding to the transparent part M1 is removed, the photoresist layer P corresponding to the translucent portion M2 is partially removed in thickness to be a first photoresist pattern P1, and the photoresist layer P corresponding to the shielding portion M3 remains intact to be a second photoresist pattern P2. At this time, the first photoresist pattern P1 has a smaller thickness than that of the second photoresist pattern P2.

Also, the first etching operation collectively removes the transparent conductive layer 252 and the second conductive layer 253 in the thin film transistor region, the boundary region between the data line 261 and the pixel electrode 260, and in the region overlying the gate pad.

Here, the data line 261 and the pixel electrode 260 in area II-II′ are etched at the same time. Accordingly, unlike the conventional art where a variation in spacing from the data line 261 to adjacent pixel electrodes 260 occurs due to the use of different masks, the embodiment of the present invention renders the distances d1 and d2 from the data line 261 to the adjacent pixel electrodes 260 the same.

Thereafter, as shown in FIG. 5G, the first photoresist pattern P1 on the pixel electrode 260 is removed through plasma ashing, thereby exposing the second conductive layer 253. At this time, the active layer 230 having the first conductive layer 251 formed thereon is not subjected to the ashing.

Also, as shown in FIG. 5H, a second etching operation is carried out to selectively remove the second conductive layer 253 and thereby exposing the upper portion of the pixel electrode 260. Here, the second etching operation may be either dry etching or wet etching but the wet etching is preferred. At this time, the active layer 230 is not subjected to the second etching operation as the first conductive layer 251 serves as protection.

Subsequently, as shown in FIG. 5I, a third etching operation may be carried out to remove the first conductive layer 251 and the ohmic contact layer on the active layer 230. At this time, the channel region of the active layer 230 is exposed to the outside, and the source electrode 262a and the drain electrode 262b constituted by the first conductive layer 251, the transparent conductive layer 252 and the second conductive layer 253 may be formed. Herein, the third etching operation may be either dry etching or wet etching, but the dry etching is preferred.

The reason why the first conductive layer 251 is not etched and remains from the first etching operation of the third mask process is to prevent the channel region of the active layer 230 from being damaged during the ashing and the second etching operation for exposing the upper portion of the pixel electrode 260. However, the embodiment is not limited to the above disclosure and also encompasses the following cases: the transparent conductive layer 252 remains on the active layer 230 from the first etching operation, or the ohmic contact layer remains, because the channel region of the active layer 230 can be protected in both cases.

Meanwhile, the third mask process may proceed with a multi-tone mask, or with two etching operations only. The two etching operations may encompass the case that the transparent conductive layer and the second conductive layer are etched in the first etching operation, and the second conductive layer 253 on the pixel electrode 260, and the ohmic contact layer 240 and the first conductive layer 251 on the active layer 230 are etched simultaneously in the second etching operation.

Also, as shown in FIG. 5J, a fourth mask process is carried out so that an organic insulating layer 270 can be formed on the data line 261. The organic insulating layer 270 is intended to reduce parasitic capacitance formed between the data line 261 and the common electrode 290.

The organic insulating layer 270 may be formed by applying any one of photo acryl, poly vinyl alcohol (PVA) or benzocyclobutene (BCB) onto the first substrate 200 to a thickness of 1.5 μm to 2.5 μm and then patterning the applied material by using a fourth mask.

The organic insulating layer 270 may also be located over the data line 261 and in the space between the pixel electrode 260 and the data line 261 so as to cover the upper portion of the data line 261 and both side surfaces of the data line 261. In other words, the organic insulating layer may be formed from one side to the opposite side of the data line 261. Alternatively, the organic insulating layer 270 may be formed over the entire region of the first substrate. However, this may increase material costs and a vertical distance between the common electrode and the pixel electrode, which thus requires higher driving voltage and therefore higher power consumption.

Also, the organic insulating layer 270 may be shaped variously according to the shape of the fourth mask.

Subsequently, as shown in FIG. 5K, the second insulating layer 280 may be formed on the entire top surface of the first substrate 200. At this time, the second insulating layer 280 may be formed of either organic or inorganic materials, but the inorganic material such as SiNx or SiO2 is preferred.

Thereafter, as shown in FIG. 5I, a fifth mask process is carried out to form first cont hole 281 and a second contact hole 282. At this time, the first contact hole 281 is formed in the gate pad region and exposes one region of the gate line 211, and the second contact hole 282 is formed in the data pad region and exposes one region of the data line 261.

As shown in FIG. 5M, a sixth mask process is carried out to forma common electrode 290, a gate connection pattern 291, and a data connection pattern 292.

The common electrode 290 may be formed on the entire top surface of the second insulating layer 280, excluding the thin film transistor region, the gate pad region and the data pad region. In this case, the common electrode 290 may have a plurality of slits in its region corresponding to the pixel electrode 260, and overlaps the region where the data line 261 has been formed. The gate connection pattern 291 and the data connection pattern 292 are formed in the first contact hole 281 and the second contact hole 282, respectively so as to electrically contact the gate line 211 and the data line 261. Meanwhile, the common electrode 290, the gate connection pattern 291 and the data connection pattern 292 may be formed of a transparent conductive material such as indium tin oxide (ITO) or indium zinc oxide (IZO).

Thereafter, an alignment layer may be applied onto the first substrate 200 having the common electrode thereon, and the second substrate is attached to the first substrate 200 to face each other, and a liquid crystal layer may be interposed between the first substrate 200 and the second substrate, wherein negative-type liquid crystal may be provided over the region corresponding to the organic insulating layer 270 as describe above.

In the method of fabricating the liquid crystal display device according to the second embodiment of the present invention, different spacing from the data line 261 to adjacent pixel electrodes 260 is prevented and the organic insulating layer 270 is formed so that influence of parasitic capacitance can be reduced, and the absence of a contact hole allows for an improved aperture ratio. Furthermore, since a separate mask process for forming a contact hole and a pixel electrode is not performed, process productivity can be improved, and product manufacturing costs can be reduced.

Also, the method of fabricating the liquid crystal display device according to the first embodiment is identical to the method of fabricating the liquid crystal display device according to the second embodiment, except for the forming of the organic insulating layer. Therefore, the liquid crystal display device according to the first embodiment is fabricated through total five mask processes, and a liquid crystal display device without any height difference between a data line and a pixel electrode is fabricated.

The embodiments of the present invention have described fringe field switching (FFS) LCDs only, but the present invention is not limited thereto. That is, TN type or VA type liquid crystal display devices and methods of fabricating the same may also be included in embodiments of the present invention provided that they include simultaneously forming source and drain electrodes, a pixel electrode, and a data line through one mask process, and maintaining uniform spacing between the pixel electrode and the data line.

The foregoing embodiments and advantages are merely exemplary and are not to be considered as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds are therefore intended to be embraced by the appended claims.

What is claimed is:

1. A liquid crystal display device comprising:
a first substrate;
a gate line and a gate electrode on the first substrate;
a first insulating layer over the first substrate having the gate line and the gate electrode;
an active layer on the first insulating layer;
a source electrode and a drain electrode on the active layer, the source electrode and the drain electrode including a first conductive layer, a transparent conductive layer and a second conductive layer being sequentially disposed;
a data line connected to the source electrode on the first insulating layer, the data line being formed by the transparent conductive layer and the second conductive layer;
a pixel electrode connected to the drain electrode on the first insulating layer, the pixel electrode being formed by the transparent conductive layer;
an organic insulating layer on the data line;
a second insulating layer over the entire upper surface of the first substrate having the organic insulating layer;
a common electrode on the second insulating layer to be overlap with the pixel electrode and the organic insulating layer, and the common electrode and the pixel electrode generating a fringe electric field;
a second substrate attached to the first substrate; and
a liquid crystal layer between the first substrate and the second substrate.

2. The liquid crystal display device of claim 1, wherein the distance between the pixel electrode and the data line is same as the distance between the neighboring pixel electrode and the data line.

3. The liquid crystal display device of claim 1, wherein the organic insulating layer is formed from one side portion of the data line to the opposite side portion of the data line.

4. The liquid crystal display device of claim 1, wherein the organic insulating layer is formed of photo acryl.

5. The liquid crystal display device of claim 4, wherein the second insulating layer is formed of SiNx or SiO₂.

6. The liquid crystal display device of claim 1, wherein the liquid crystal layer in a region corresponding to the organic insulating layer is formed of negative-type liquid crystal.

7. The liquid crystal display device of claim 1, wherein the data line is connected to the first conductive layer and the transparent conductive layer of the source and drain electrodes, and
the pixel electrode is connected to the transparent conductive layer of the drain electrode.

8. The liquid crystal display device of claim 1, further comprising an ohmic contact layer between the active layer and the first conductive layer.

9. A method of fabricating a liquid crystal display device, the method comprising:
forming a gate line and a gate electrode on a first substrate;
sequentially forming a first insulating layer, an active layer and a first conductive layer over the first substrate;
sequentially forming a transparent conductive layer and a second conductive layer on the first insulating layer having the active layer and the first conductive layer thereon;
patterning the first conductive layer, the transparent conductive layer, and the second conductive layer by single mask process to form source and drain electrodes including the first conductive layer, the transparent conductive layer and the second conductive layer, a data line including the transparent conductive layer and the second conductive layer, and a pixel electrode having the transparent conductive layer;
introducing a liquid crystal layer between the first substrate and the second substrate; and
attaching a second substrate to the first substrate,
wherein the distance between the pixel electrode and the data line is same as the distance between the neighboring pixel electrode and the data line.

10. The method of claim 9, wherein the forming of the first insulating layer, the active layer, and the first conductive layer comprises:
sequentially depositing the first insulating layer, the active layer, and the first conductive layer; and
patterning by single mask process the active layer and the first conductive layer to form the first insulating layer, the active layer, and the first conductive layer in the same shape to be overlapped with the gate electrode.

11. The method of claim 9, wherein the forming of the source and drain electrodes, the data line, and the pixel electrode formed using a half-tone mask.

12. The method of claim 9, wherein, the forming of the source and drain electrodes, the data line, and the pixel electrode, the pixel electrode includes:
forming the pixel electrode with a first etching process;
exposing an upper portion of the pixel electrode with a second etching process; and
forming the source and drain electrodes with a third etching process.

13. The method of claim 12, wherein the forming of the source and drain electrodes, the data line, and the pixel electrode includes:
forming a first photoresist pattern on the second conductive layer corresponding to the pixel electrode and a second photoresist pattern on the second conductive layer corresponding to the source and drain electrodes and the data line using a half-ton mask to, the second photoresist pattern being thicker than the first photoresist pattern; and
etching the transparent conductive layer and the second conductively layer to form the pixel electrode;
removing the first photoresist pattern by ashing;
etching the second conductive layer on the pixel electrode to expose the upper portion of the pixel electrode;
etching the first conductive layer on the active layer to expose an upper portion of the active layer and forming the source and drain electrodes; and
taking off the second photoresist pattern.

14. The method of claim 9, further comprising:
forming a second insulating layer on the first insulating layer having the source and drain electrodes, the data line, and the pixel electrode thereon after the forming of the source and drain electrodes, and the pixel electrode; and
forming a common electrode in an region where the common electrode is overlapped with the pixel electrode and the data line on the second insulating layer, the common electrode and he pixel electrode generating a fringe electric field.

15. The method of claim 14, further comprising, after the forming of the data line and prior to the forming of the insulating layer, forming an organic insulating layer on the data line.

16. The method of claim 15, wherein the organic insulating layer is formed from one side portion of the data line to the opposite side portion of the data line.

17. The method of claim 15, wherein the organic insulating layer is formed of photo acryl, poly vinyl alcohol (PVA), or benzocyclobutene (BCB).

18. The method of claim 15, wherein the liquid crystal layer includes negative-type liquid crystal layer interposed over a region corresponding to an upper portion of the organic insulating layer.

19. The method of claim 9, wherein the first conductive layer is formed of material selected from the group consisting of Mo, MoTi, Ti, Ti alloy, and Al, the second conductive layer is formed of material selected from the group consisting of Cu, Al, Ag, Pt, or Au, and the transparent conductive layer is formed of material selected from the group consisting of indium tin oxide (ITO) or indium zinc oxide (IZO).

20. The method of claim 9, wherein, forming of the first insulating layer, the active layer, and the first conductive layer further includes an ohmic contact layer between the active layer and the first conductive layer.
